(19) United States
(12) Patent Application Publication
(10) Pub. No.: US 2006/0208293 A1
(43) Pub. Date: Sep. 21, 2006

(54) Color filter substrate for liquid crystal display device and method for fabricating the same

(75) Inventors: Ji Chul Lim, Gyeongsangbuk-do (KR); Sang Don Yang, Seoul (KR)

Correspondence Address: MORGAN LEWIS & BOCKIUS LLP, 1111 PENNSYLVANIA AVENUE NW, WASHINGTON, DC, 20004, US

(73) Assignee: LG.Philips LCD Co., Ltd.

(21) Appl. No.: 11/374,984

(22) Filed: Mar. 15, 2006

(30) Foreign Application Priority Data
Mar. 19, 2005 (KR) 2005-22949

(51) Int. Cl. H01L 31/062; H01L 21/00

(52) U.S. Cl. 257/294; 438/70; 257/E31.121

(57) ABSTRACT

A method for fabricating a color filter substrate for a liquid crystal display device having a RGBW pixel structure, wherein a white sub-color filter layer is formed during a process of forming a planarization layer with a step, and a spacer pattern is formed on the white sub-color filter layer for compensating for the step of the planarization layer.

This application claims the benefit of Korean Patent Application No. 22949/2005 filed in Korea on Mar. 19, 2005, which is hereby incorporated by reference.

### BACKGROUND OF THE INVENTION

1. Field of the Invention

The present invention relates to a color filter substrate for a liquid crystal display (LCD), and more particularly, to a color filter substrate for an LCD, which includes a spacer for a step of a color filter without complicating a fabrication process, and a method for fabricating the same.

2. Background of the Related Art

With development of the information technology society, display devices are in great demand. To meet the demand, much effort has been made to research and develop various types of display devices, such as a liquid crystal display device (LCD), a plasma display panel (PDP), an electro luminescent device (ELD), a vacuum fluorescent display (VFD), and the like. Among them, the LCD has been widely utilized because of its advantageous characteristics of slim profile, lightweight, and low power consumption. The LCDs are optimum monitors for TVs and computers.

FIG. 1 is an exploded perspective view schematically illustrating a structure of a liquid crystal panel according to the related art. As shown in FIG. 1, the related art liquid crystal panel includes a color filter substrate, an array substrate, and a liquid crystal layer interposed between the color filter substrate and the array substrate. Herein, the color filter substrate may be configured with an upper substrate 5 formed of a transparent insulating substrate, a plurality of black matrixes 6 formed on the upper substrate 5, and red, green and blue sub-color filter layers 8a, 8b and 8c respectively formed in each grid space between the plurality of black matrixes 6. The array substrate may be configured with a gate line 13 and a data line 15 that are intersected with each other to define a pixel region P, a pixel electrode 17 formed in the pixel region P, and a thin film transistor (TFT) T disposed at an intersection region of the gate line 13 and the data line 15. Moreover, the pixel electrode 17 formed in the pixel region P may be formed of a transparent conductive metal with an excellent transmissivity, e.g., indium-tin-oxide (ITO).

FIGS. 2A to 2F are cross-sectional views taken along the line A-A′ of FIG. 1. These drawings represent a process sequence schematically illustrating a method for fabricating a color filter substrate according to the related art. As shown in FIG. 2A, a photosensitive black organic material is coated on the upper substrate 5 to form a black organic layer 4. A mask 19 is then disposed over the black organic layer 4. The mask 19 may be configured with a pattern including transmission part A and a blocking part B. Thus, light is irradiated on the black organic layer 4 corresponding to the transmission part A of the mask 19 to develop the black organic layer 4, thereby forming the plurality of black matrixes 6, as illustrated in FIG. 2B.

After that, as illustrated in FIG. 2C, first, a red color resin is coated on the entire surface of the upper substrate 5 where the black matrixes 6 are formed, and then is selectively exposed to the light so as to form a red sub-color filter array 8a in a desired region. Second, a green color resin is coated over the entire surface of the upper substrate 5, and then is selectively exposed to the light to thereby form a green sub-color filter layer 8b. Third, a blue color resin is coated over the entire surface of the upper substrate 5, and then is selectively exposed to the light to form a blue sub-color filter layer 8c.

Next, as shown in FIG. 2D, a white color resin 14 is coated on the red, green and blue color filter layers 8a, 8b and 8c as well as an exposed surface of the upper substrate 5. Thereafter, a mask 29 is disposed over the white color region 14, wherein the mask 29 is configured with a pattern including the transmission part A and the blocking part B. Thus, the light is irradiated on the white color resin 14 corresponding to the transmission part A of the mask 29 and to develop the white color resin 14, thereby forming a white sub-color filter layer 8d as illustrated in FIG. 2E. The white sub-color filter layer 8d and the red, green and blue sub-color filter layers 8a, 8b and 8c constitute a unit pixel with red, green, blue and white (RGBW) color filters.

Finally, as shown in FIG. 2F, a transparent resin is coated over the upper substrate 5 to form a planarization layer 46 for planarizing the upper substrate 5 where the sub-color filter layers 8a to 8d are formed. After the planarization layer 46 is formed over the upper substrate 5, a spacer (not shown) is formed on the planarization layer 46 for maintaining a cell gap.

However, as described above, in order to form the white sub-color filter layer 8d in the related art color filter substrate, it is necessary to perform an additional masking process, which complicates the fabrication process and increases the fabrication costs.

### SUMMARY OF THE INVENTION

Accordingly, the present invention is directed to a color filter substrate for a liquid crystal display (LCD) device and a method for fabricating the same that substantially obviates one or more problems due to limitations and disadvantages of the related art.

An object of the present invention is to provide a color filter substrate that is able to simplify a fabrication process by substituting a white sub-color filter layer with a planarization layer, and to overcome a step defect occurring in the white sub-color filter layer by forming a spacer on the white sub-color filter layer, and a method for fabricating the same.

Additional advantages, objects, and features of the invention will be set forth in part in the description which follows, and in part will become apparent from the description, or may be learned from practice of the invention. The objectives and other advantages of the invention will be realized and attained by the structure particularly pointed out in the written description and claims hereof as well as the appended drawings.

To achieve these objects and other advantages and in accordance with the purpose of the present invention, as embodied and broadly described herein, there is provided a color filter substrate including a plurality of black matrixes formed on a substrate, red, green, blue and white sub-color filter layers formed in grid spaces of the black matrixes, respectively, a planarization layer formed on the color filter layer, wherein part of the planarization layer is formed as the white sub-color filter layer, and first and second spacers on the planarization layer, the first spacer maintaining a cell gap and a second spacer compensating for a step of the planarization layer.

In another aspect of the present invention, there is provided a method for fabricating a color filter substrate, the method including forming a plurality of black matrixes on a substrate, forming red, green and blue sub-color filter layers between the black matrixes, forming a planarization layer on the substrate where the sub-color filter layers are formed, while simultaneously forming a white sub-color filter layer, and forming a first spacer and a second spacer on the substrate where the planarization layer is formed, wherein the first spacer maintains a cell gap and a second spacer compensates for a step of the planorization layer.

Still in another aspect of the present invention, there is provided a method for fabricating a color filter substrate includes forming a plurality of black matrixes on a substrate, wherein the plurality of black matrixes includes grid spaces, forming a color filter layer including red, green and blue sub-color filter layers in the grid spaces of the plurality of black matrixes, forming a planarization layer on an entire surface of the substrate, wherein a first part of the planarization layer is formed on the red, green and blue sub-color filter layers, a second part of the planarization layer is formed as a white sub-color filter layer on the substrate, a step is formed between the first and second parts of the planarization layer, forming a first spacer on the first part of the planarization layer to maintain a cell gap, and forming a second spacer on the second part of the planarization layer to compensate the step.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is an exploded perspective view schematically illustrating a structure of a liquid crystal panel according to the related art;

FIGS. 2A to 2F are cross-sectional views taken along the line A-A′ of FIG. 1, which represent a process sequence schematically illustrating a method for fabricating the color filter substrate according to the related art; and

FIGS. 3A to 3F are cross-sectional views illustrating a method for fabricating a color filter substrate according to an exemplary embodiment of the present invention.

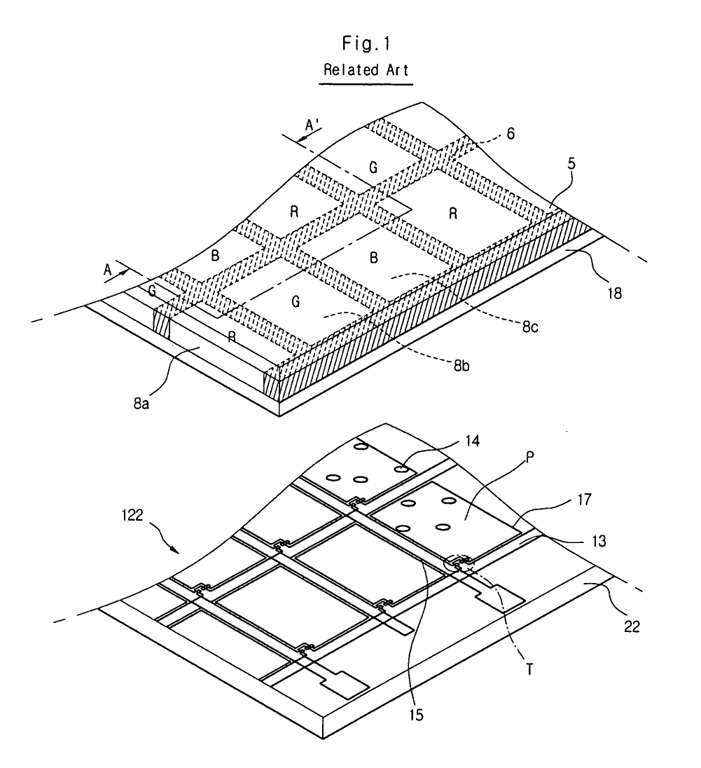

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

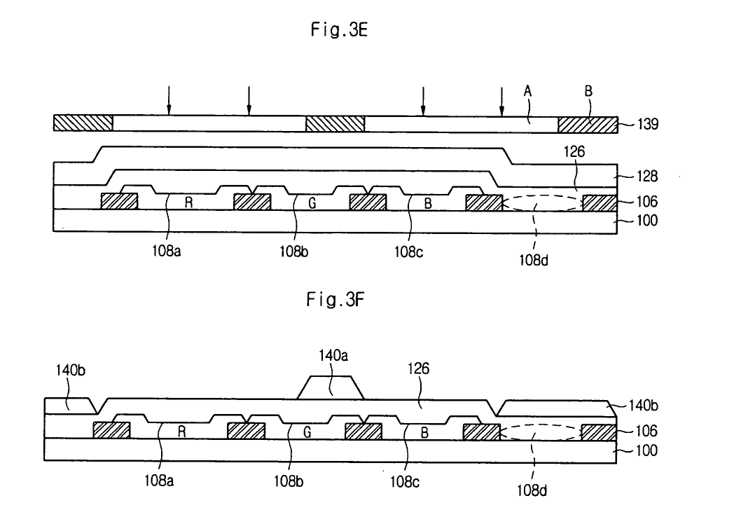

FIGS. 3A to 3F are cross-sectional views schematically illustrating a method for fabricating a color filter substrate according to an exemplary embodiment of the present invention. As shown in FIG. 3A, a photosensitive black organic material is coated on a transparent insulating substrate 100 to form a black organic layer 104. The photosensitive black organic material is typically classified into a positive type in which a portion that the light is irradiated on is developed, and a negative type in which a portion that the light is not irradiated on is developed. In this exemplary embodiment, the positive type is utilized for illustration. After the black organic layer 104 is formed, a mask 119 is then disposed thereon. The mask 119 may be configured with a pattern including a blocking part B and a transmission part A. Thus, when the light is irradiated on the mask 119 to develop the black organic layer 104, the black organic layer 104 corresponding to the blocking part A of the mask 119 remains intact, thereby forming a plurality of black matrixes 106, as illustrated in FIG. 3B.

FIG. 3C is a cross-sectional view schematically illustrating a process for forming a color filter using red (R), green (G) and blue (B) color resin. The color resin may include a photosensitive composite such as a photoinitiator, a monomer or a binder, and an organic pigment showing R/G/B color or similar color to R/G/B. During the process, a red color resin is first coated on an entire surface of the insulating substrate 100 where the black matrix 106 is formed. Then, the red color resin is selectively exposed to the light so as to form a red sub-color filter array 108a in a desired region. After the red sub-color filter layer 108a is formed, a green color resin is sequentially coated over the entire surface of the insulating substrate 100, and is then selectively exposed to the light to thereby form a green sub-color filter layer 108b. Finally, a blue color resin is coated over the entire surface of the insulating substrate 100, and is then selectively exposed to the light so as to form a blue sub-color filter layer 108c. In this exemplary embodiment of the present invention, while the process of forming the color filter is in sequence of the red, the green and the blue color, it is unnecessary to obey this sequence.

After the red, green and blue sub-color filter layers 108a, 108band 108c are formed on the insulating substrate 100, as shown in FIG. 3C, there is an empty grid space between the black matrixes 106. This grid space is emptied to form a white sub-color filter layer. Referring to FIG. 3D, a planarization layer 126 formed of a transparent resin is deposited over the insulating substrate 100 for planarizing the insulating substrate 100. The empty grid space between the black matrixes 106 is filled by the planarization layer 126, thereby forming a white sub-color filter layer 108d. Thus, a unit pixel is configured with the red, green, blue and white color filter layers 108a, 108b, 108c and 108d that are formed on the insulating substrate 100. As describe above, such a configuration of the exemplary embodiment can improve luminance characteristics of every unit pixel.

As shown in FIG. 3D, there is a step formed between the planarization layer 126 formed on the red, green and blue sub-color filter layers 108a, 108b and 108c, and the planarization layer 126 formed on the region of the white sub-color filter layer 108d. Such a step may cause a problem in that the uniform luminance characteristics of the unit pixel may be deteriorated. To resolve the problem, the color filter substrate of the exemplary embodiment is provided with a spacer pattern to fill the step during a process of forming a typical spacer for a cell gap.

FIG. 3E is a cross-sectional view schematically illustrating a process of forming the spacer pattern on the insulating substrate 100 where the planarization layer 126 is formed. As shown in FIG. 3E, a photosensitive organic material is coated on the entire surface of the insulating substrate 100 where the planarization layer 126 is formed, so that a photosensitive organic layer 128 is formed on the planarization layer 126. In general, the photosensitive organic material utilizes the positive type photosensitive material. Then, a mask 139 is disposed over the insulating substrate 100 where the photosensitive organic layer 128 is formed. The mask 139 is configured with the pattern including the transmission part A and the blocking part B. The blocking part B is disposed corresponding to a portion of the insulating substrate 100 over which the spacer pattern is to be formed. Thus, by irradiating the light over the photosensitive organic layer 128 through the transmission part A of the mask 139 and developing it, as shown in FIG. 3F, a first spacer 140a and a second spacer 140b are formed with predetermined configurations. Specifically, the first spacer 140a is formed on the planarization layer 126 and above the sub-color filter layers 108a, 108b and 108c, whereas the second spacer 140b is formed on the white sub-color filter layer 108d that is disposed next to the blue sub-color filter layer 108c. In other words, the second spacer 140b is formed on the planarization layer 126 which is utilized as the white sub-color filter layer 108d, thereby overcoming the step defect.

In the exemplary embodiment, the first and second spacers 140a and 140b may be formed of a transparent material capable of transmitting light generated from a backlight unit (not shown) therethrough. The first spacer 140a formed above the red, green and blue sub-color filter layers 108a, 108b and 108c serves as a typical spacer for maintaining the cell gap between a lower substrate (not shown), i.e., an array substrate, and an upper substrate, i.e., the color filter substrate. On the other hand, the second spacer 140b serves to fill the step between the planarization layer 126 formed on the white sub-color filter layer 108d and the planarization layer 126 formed on the red, green and blue sub-color filter layers 108a, 108b and 108c. In other words, the second spacer 140b is formed on a lower portion of the step caused by the formation of the planarization layer 126.

While the second spacer 140b is formed by patterning the photosensitive organic layer 128 using the mask 139, edges of the second spacer 140b may not be patterned well, thereby causing a problem in that the edges of the second spacer 140b appear on an image when the image is displayed on the insulating substrate 100. To resolve the problem, the second spacer 140b may be formed such that the edges thereof are shielded by the black matrixes 106 formed on the insulating substrate 100, thereby preventing the edges of the second spacer 140b from appearing on the image that is displayed on the insulating substrate 100.

In the exemplary embodiment of the present invention, the plurality of black matrixes 106 are formed on the transparent insulating substrate 100, and then the red, green and blue sub-color filter layers 108a, 108b and 108c are formed between the plurality of black matrixes 106. After that, the white sub-color filter layer 108d is formed using the planarization layer 126 to thereby fabricate the color filter substrate.

On the contrary, in case of the existing color filter substrate, since the color filter substrate employs a unit pixel configured with the red, green and blue sub-color filter layers, the quantity of light that the white light generated from the backlight is transmitted through the color filter is small, thereby causing low luminance. In the exemplary embodiment of the present invention, since a unit pixel is configured with the red, green, blue and white sub-color filter layers, the luminance characteristics are enhanced.

As described above, the first spacer 140a serves to maintain the cell gap between the insulating substrate 100 and the lower substrate (not shown), and the second spacer 140b is formed on the lower portion of the step, thereby filling the step generated during the formation of the planarization layer 126. More specifically, since the second spacer 140b is formed on the planarization layer 126 on the region of the white sub-color filter layer 108d, the step can be thus filled between the planarization layer 126 formed on the red, green and blue color filter layers 108a, 108b and 108c and the planarization layer 126 formed on the region of the white sub-color filter layer 108d. If the second spacer 140b is not patterned well during the patterning process, the edges of the second spacer 140b may be reflected on a predetermined image displayed on the insulating substrate 100. To resolve the problem, the edges of the second spacer may be shielded by the black matrixes 106, thereby preventing the edges of the second spacer 140b from appearing on the image that is displayed on the insulating substrate 100.

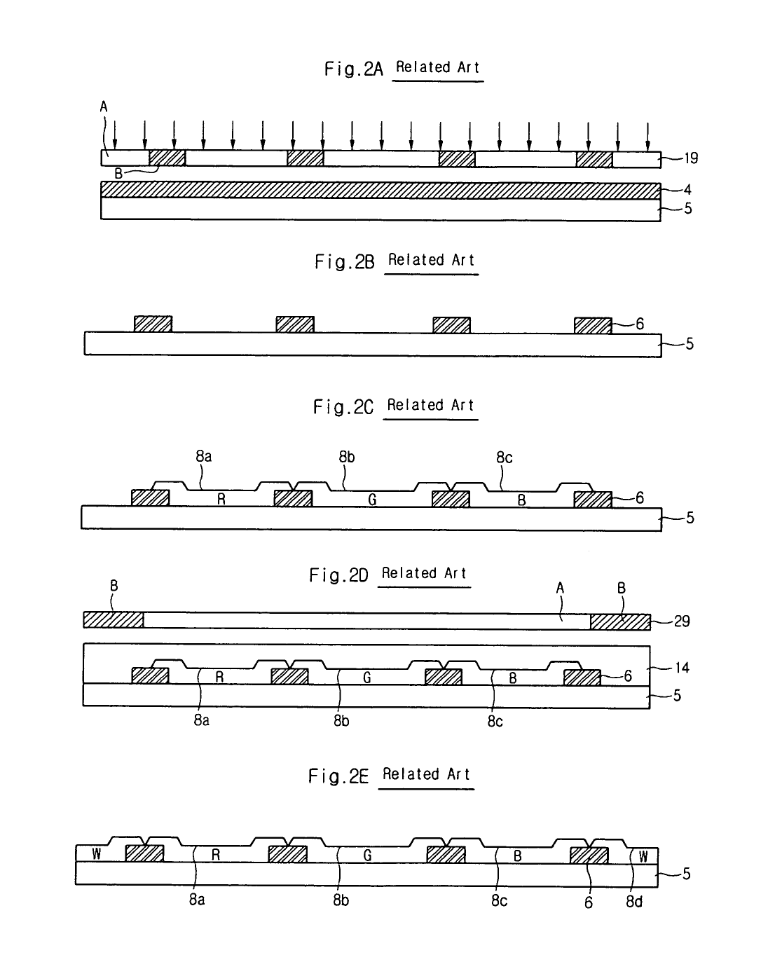

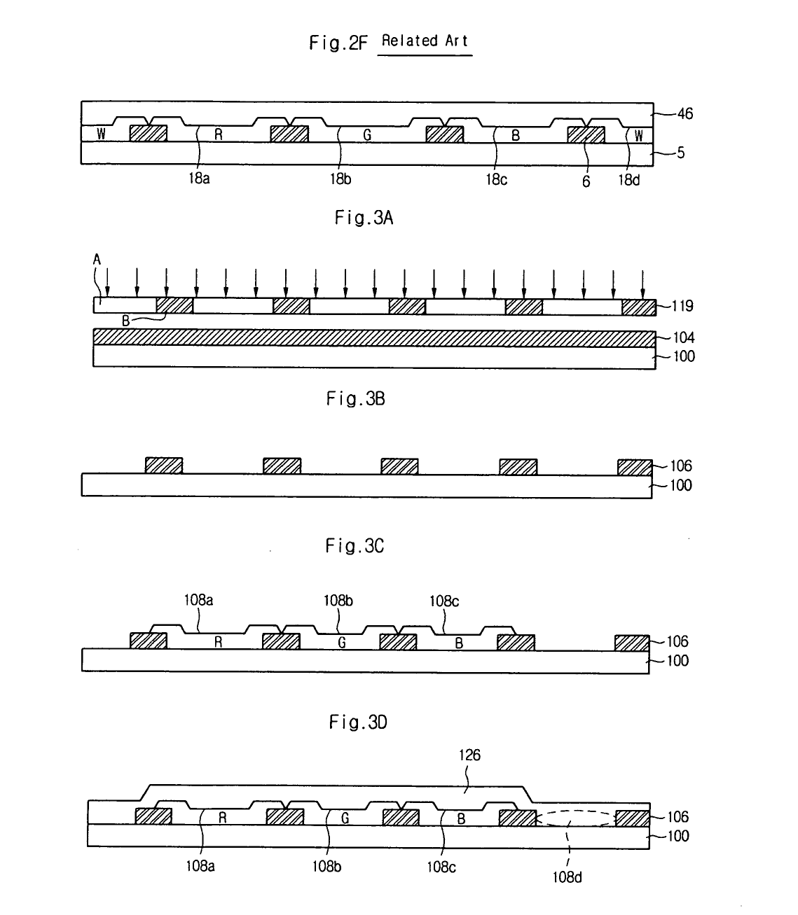

In the related art, in order to fill the step formed between the sub-color filter layers 8a, 8b, 8c and 8d and the planarization layer 126, the white sub-color filter layer 8d (of FIG. 2E) is formed through an additional masking process using a white color resin or a transparent resin. Thus, an additional mask is required to be separately used in forming the white sub-color filter layer 8d, thereby increasing the fabrication costs and complicating the fabrication process. In contrast to the related art, in the present invention, the white sub-color filter layer of the exemplary embodiment is not separately formed on the insulating substrate corresponding to the white color filter region. As described above, the second spacer 140b is formed on the lower portion of the step of the planarization layer 126 over the white color filter region during the process of forming the first spacer 140a, i.e., the typical spacer for the cell gap. In other words, the step defect of the planarization layer 126 is remedied without the additional masking process.

As described above, according to the exemplary embodiment for the inventive method of fabricating the color filter substrate, the plurality of black matrixes and the red, green and blue color filter layers are formed on the transparent insulating substrate, wherein the white sub-color filter region is disposed next to the blue sub-color filter layer. Thereafter, the planarization layer is formed for planarizing the insulating substrate. Forming the planarization layer generates the step between the sub-color filter layer and the planarization layer on the insulating substrate. However, by forming the spacer, the step defect can be remedied. In the exemplary embodiment, the spacer is formed on the lower portion of the step between the sub-color filter layer and the planarization layer during the same process of forming the typical spacer for maintaining the cell gap. Accordingly, the step defect is thus remedied without requiring the additional masking process.

According to the inventive method of the exemplary embodiment, since the white sub-color filter layer is formed simultaneously with the formation of the planarization layer after forming the red, green and blue sub-color filter layers, the fabrication process is simplified. In addition, since the spacer pattern is formed on the white sub-color filter layer, the step defect between adjacent planarization layers is thus remedied.

It will be apparent to those skilled in the art that various modifications and variations can be made in the color filter substrate and method for fabricating the same of the present invention. Thus, it is intended that the present invention cover the modifications and variations of this invention provided they come within the scope of the appended claims and their equivalents.

What is claimed is:

1. A color filter substrate comprising:
a substrate;
a plurality of black matrixes formed on the substrate;
a color filter layer including red, green, blue and white sub-color filter layers formed between the plurality of black matrixes, respectively;
a planarization layer formed on the color filter layer and having a step; and
first and second spacers formed on the planarization layer, wherein the first spacer maintains a cell gap and the second spacer compensates for the step of the planarization layer.

2. The color filter substrate according to claim 1, wherein the substrate is formed of a transparent insulating material.

3. The color filter substrate according to claim 1, wherein the second spacer is formed on the white sub-color filter.

4. The color filter substrate according to claim 1, wherein the first and second spacers are formed of a transparent material.

5. The color filter substrate according to claim 3, wherein the second spacer includes edges that are disposed over the black matrixes.

6. A method for fabricating a color filter substrate, the method comprising:
forming a plurality of black matrixes on a substrate;
forming a color filter layer including red, green and blue sub-color filter layers between the plurality of black matrixes;
forming a planarization layer on an entire surface of the substrate including the sub-color filter layers, and simultaneously forming a white sub-color filter layer on the substrate, wherein the planarization layer includes a step; and
forming a first spacer and a second spacer on the planarization layer wherein the first spacer maintains a cell gap and a second spacer compensates for the step.

7. The method according to claim 6, wherein the first and second spacers are simultaneously formed.

8. The color filter substrate according to claim 6, wherein the second spacer is formed on the white sub-color filter layer.

9. The method according to claim 6, wherein the first and second spacers are formed of a transparent material.

10. The method according to claim 6, wherein the white sub-color filter layer is formed during the step of forming the planarization layer.

11. The method according to claim 8, wherein the second spacer includes edges that are disposed over the black matrixes.

12. A method for fabricating a color filter substrate, the method comprising:
forming a plurality of black matrixes on a substrate, wherein the plurality of black matrixes includes grid spaces;
forming a color filter layer including red, green and blue sub-color filter layers in the grid spaces of the plurality of black matrixes;
forming a planarization layer on an entire surface of the substrate, wherein a first part of the planarization layer is formed on the red, green and blue sub-color filter layers, a second part of the planarization layer is formed as a white sub-color filter layer on the substrate, a step is formed between the first and second parts of the planarization layer;
forming a first spacer on the first part of the planarization layer to maintain a cell gap; and
forming a second spacer on the second part of the planarization layer to compensate the step.

13. The method according to claim 12, wherein the first and second spacers are simultaneously formed.

14. The color filter substrate according to claim 12, wherein the first and second spacers are formed of a transparent material.

15. The method according to claim 12, wherein the second spacer includes edges that are disposed over the black matrixes.
